(19) United States
(12) Patent Application Publication
(10) Pub. No.: US 2021/0017653 A1
(43) Pub. Date: Jan. 21, 2021

(54) PHOTOELECTROCHEMICAL (PEC) CELL

(71) Applicant: King Abdullah University of Science and Technology, Thuwal (SA)

(72) Inventors: Jr-Hau HE, Thuwal (SA); Hui-Chun FU, Thuwal (SA); Purushothaman VARADHAN, Thuwal (SA)

(21) Appl. No.: 17/043,905

(22) PCT Filed: Apr. 12, 2019
(86) PCT No.: PCT/IB2019/053046

§ 371 Date: Sep. 30, 2020

Related U.S. Application Data
(60) Provisional application No. 62/657,073, filed on Apr. 13, 2018.
(60) Provisional application No. 62/659,398, filed on Apr. 18, 2018.

(51) Int. Cl. C25B 1/00; H01L 31/068; C25B 11/04; H01L 31/0216; H01L 31/18; C01B 13/02; C25B 1/04; H01L 31/0224

(52) U.S. Cl. CPC C25B 1/003; H01L 31/0682; C25B 11/0405; H01L 31/022441; H01L 31/1868; C01B 13/0207; C25B 1/04; H01L 31/02167

(57) ABSTRACT

A photoelectrochemical (PEC) cell for splitting water into hydrogen and oxygen is described herein. The PEC cell includes a first side configured to capture electromagnetic energy. The PEC cell further includes a second side opposed to the first side comprising an anode electrode and a cathode electrode. The PEC cell further includes a buried p-n junction that converts electromagnetic energy received at the first side into electrical energy. The electrical energy is used to catalyze oxygen and hydrogen at the second side of the PEC cell.

### CROSS-REFERENCE TO RELATED APPLICATIONS

This application claims the benefit of U.S. Provisional Patent Application No. 62/657,073, filed Apr. 13, 2018, and of U.S. Provisional Patent Application No. 62/659,398, filed Apr. 18, 2018, both of which are incorporated by reference herein in their entirety.

### BACKGROUND

Traditionally, fossil fuels have served as a primary energy source for much of the world's energy needs. However, fossil fuels are undesirable because their use results in substantial pollution being released into the environment. As such, alternative fuel sources that release less pollution into the environment are generally desirable.

One fuel source being investigated as an alternative to fossil fuels is hydrogen, because hydrogen can be safely transported converted to usable energy with little or no pollution being released into the environment, as the primary by-product is of hydrogen fuel cell operation is liquid water. One significant impediment to adoption of hydrogen as a fuel source is that the creation of hydrogen requires substantial energy and therefore cost.

One way to generate hydrogen is to split liquid water, an abundant resource on our planet, into hydrogen and oxygen. Since sunlight is an unlimited resource on our planet, some have attempted to develop photoelectrochemical (PEC) cells designed to collect energy from incident sunlight, and use the collected energy to separate water molecules into oxygen and hydrogen useable as a fuel. While some success has been found developing PEC cells, they suffer from significant drawbacks, such as low efficiency and short longevity. As such, a need exists to provide improvements in PEC cells for water splitting.

### SUMMARY

According to one aspect of the disclosure, a photoelectrochemical (PEC) water splitting cell is comprised of a semiconductor layer and an electrode layer arranged at a second surface of the semiconductor layer. The semiconductor layer comprises a light capture surface arranged at a first side, wherein the semiconductor layer comprises a buried junction configured to convert incident electromagnetic energy into electrical energy. The electrode layer includes an anode electrode configured to catalyze hydrogen, and a cathode electrode configured to catalyze oxygen.

According to another aspect, a method of forming a photoelectrochemical cell includes patterning a first side of a semiconductor substrate. The method further includes doping a second side of the semiconductor substrate to form a buried junction layer, wherein the buried junction layer comprises a first plurality of doped regions and a second plurality of doped regions arranged in an alternating pattern and forming an electrode layer at the second side of the semiconductor substrate, wherein the electrode layer includes an anode electrode comprising a first plurality of fingers arranged in an interdigitated alternating pattern with a cathode electrode comprising a second plurality of fingers.

According to another aspect of the disclosure, a method includes receiving, at a first side of a photoelectrochemical (PEC) cell, electromagnetic energy. The method further includes converting, via a buried junction of the PEC cell, the received electromagnetic energy into electrical energy and using, at an anode electrode and a cathode electrode arranged at a second side of the PEC cell, the converted electrical energy to catalyze water into hydrogen and oxygen.

### BRIEF DESCRIPTION OF THE DRAWINGS

FIG. 1 is a conceptual diagram illustrating a side view one example of a photoelectrochemical (PEC) consistent with one or more aspects of this disclosure.

FIG. 2 is a conceptual diagram illustrating a side view one example of a photoelectrochemical (PEC) consistent with one or more aspects of this disclosure.

FIG. 3 is a conceptual diagram illustrating one example of a top-down view of an electrode layer of a PEC cell according to one or more aspects of this disclosure.

FIG. 4 is a conceptual diagram illustrating the respective components of a PEC cell consistent with one or more aspects of this disclosure.

FIG. 5 is a photographic image depicting one example of an electrode layer of a PEC cell consistent with one or more aspects of this disclosure.

FIG. 6 is a conceptual diagram illustrating three PEC cells coupled to one another in series consistent with one or more aspects of this disclosure.

FIG. 7 is a photographic image depicting three PEC cells coupled to one another in series consistent with one or more aspects of this disclosure.

FIG. 8 is a conceptual diagram depicting one example of a PEC module comprising a plurality of PEC cells consistent with one or more aspects of this disclosure.

FIG. 9 is a flow diagram depicting one example of a method of making a PEC cell consistent with one or more aspects of this disclosure.

FIG. 10 is a flow diagram depicting one example of a method of using a PEC cell consistent with one or more aspects of this disclosure.

### DETAILED DESCRIPTION

This disclosure is directed to devices, methods, and techniques providing for improvements in water splitting to generate hydrogen which may be used for numerous applications, including as a “clean” (low emissions) energy source.

A potential solution for storing converted solar energy would be to directly store solar energy in the hydrogen gas fuels or hydrocarbons that combine the advantages of large scale storage, transported, combusted, or ultimately consumed on demand using a fuel cell device to generate electricity. The solar-drive PEC water splitting consists of three fundamental steps to generate hydrogen: (i) charge carrier generation via photo-excitation, (ii) separation/transportation of charge carriers to the surfaces, and (iii) the utilization of photo-excited carriers to drive catalytic water reduction or oxidation at the surfaces.5 As the most investigated photoelectrode, Si, high-performing photon absorber with optimal bandgap (Eg=1.1 eV) has 2 dilemmas avoiding efficient solar-to-hydrogen conversion: (i) the poor kinetics without the electrocatalyst for splitting water and (ii) the small bandgap which can not straddle both reduction (0.0 VRHE) and oxidation (1.23 VRHE) potentials of water. To work around the spontaneous solar-dive hydrogen evolution constraint, the most practical and cost-effective ways for achieving efficient solar-to-hydrogen conversion is by employing an integrated PEC device configuration as described herein, in which one integrated PEC device may be coupled in series with other integrated PEC device to provide an additional voltage to a single bandgap water-splitting device for driving the hydrogen/oxygen evolution reactions. herein

For example, a photoelectrochemical (PEC) cell is described herein. The PEC cell includes a semiconductor layer comprising a light capture surface arranged at a first side. The semiconductor layer comprises a buried junction configured to convert incident electromagnetic energy into electrical energy. The PEC cell further includes an electrode layer arranged at a second surface of the semiconductor layer that includes an anode electrode configured to catalyze hydrogen, and a cathode electrode configured to catalyze oxygen.

As another example, a method of forming a photoelectrochemical cell is described herein. The method includes patterning a first side of a semiconductor substrate. The method further includes doping a second side of the semiconductor substrate to form a buried junction layer, wherein the buried junction layer comprises a first plurality of doped regions and a second plurality of doped regions arranged in an alternating pattern. The method further includes forming an electrode layer at the second side of the semiconductor substrate, wherein the electrode layer includes an anode electrode comprising a first plurality of fingers arranged in an interdigitated alternating pattern with a cathode electrode comprising a second plurality of fingers.

As another example, a method is described herein. The method includes receiving, at a first side of a photoelectrochemical (PEC) cell, electromagnetic energy. The method further includes converting, via a buried junction of the PEC cell, the received electromagnetic energy into electrical energy. The method further includes using, at an anode electrode and a cathode electrode arranged at a second side of the PEC cell, the converted electrical energy to catalyze water into hydrogen and oxygen.

Attempts have been made to use readily available electromagnetic energy, such as sunlight, to split water to generate hydrogen. For example, photoelectrochemical (PEC) cells have been developed that are capable of using sunlight to split water molecules for purposes of creating hydrogen. Such PEC cells utilize a photo-sensitive semiconductor to convert electromagnetic energy (e.g., sunlight) into electrical energy which, when submerged in an electrolyte solution (e.g., liquid water) powers catalysis of water molecules into oxygen and hydrogen at respective anode and cathode electrodes of the cell.

In a PEC cell, incident sunlight excites free electron-hole pairs in the cell. These electron-hole pairs are separated at buried p-n junction, which the electrons flow to a cathode electrode (n⁺-Si) and the holes flow to a anode electrode (p⁺-Si). At the cathode electrode, four electrons react with four water molecules to form two molecules of hydrogen and four OH⁻ groups (4H₂O(1)+4e⁻→2H₂(g)+4OH⁻(aq)). The OH⁻ groups flow through the liquid electrolyte to the surface of the anode electrode. At the anode electrode, the four OH⁻ groups react with the four holes, the result being two water molecules and an oxygen molecule (4OH⁻(aq)+4h⁺→O₂(g)+2H₂O(1)). The anode electrode may be described as configured to catalyze oxygen, while the cathode electrode may be described as configured to catalyze hydrogen.

A typical PEC cell as described above includes a non-transparent metal-based electrode (anode) arranged at a light receiving surface of the PEC. Such a typical PEC cell may also include only a single photo-sensitive p-n junction arranged in parallel to the light receiving surface of the cell.

A typical PEC cell may suffer from significant drawbacks in efficiency and longevity. For example, such a PEC cell may suffer from “shadow effects” in that non-transparent metallization (e.g., finger electrodes) block a portion of the exposed surface of the photosensitive semiconductor material, and therefore reduce the PEC cell's ability to convert received light into electrical energy. In addition, overloading or aggregation of cocatalysts may reduce the ability of a photosensitive semiconductor material to convert incident light into electrical energy, thereby reducing the efficiency of the cell to split water molecules.

This disclosure is directed to improvements in PEC cells used to split water molecules. According to some aspects, a PEC cell does not include any electrodes on the surface of the photosensitive semiconductor material configured to be exposed to light (light capture surface). Instead, both a cathode electrode and an anode electrode are arranged on a same side of the PEC cell. According to these aspects, both the anode and cathode electrodes are arranged on a side of the PEC cell opposed to a light capture surface of the cell.

According to still other aspects, a PEC cell includes one or more buried p-n junctions in the photosensitive semiconductor material. The buried junction may be arranged substantially perpendicular to the light capture surface of the semiconductor material (hereinafter referred to as a “vertical junction”), in contrast with typical PEC cell designs which include a junction arranged in parallel to the light capture surface of the PEC cell (hereinafter referred to as a “horizontal junction”). According to still other aspects, a PEC cell is described herein that includes a plurality of p-n junctions that are each vertical junctions arranged substantially in parallel to the light capture surface of the PEC cell.

According to still other aspects of this disclosure, an anode and cathode electrode of the PEC cell are arranged proximal to the buried p-n junctions of the cell, which substantially shortens the electrical path for charge carriers to travel, leading to improved operational efficiency of the PEC cell.

According to still other aspects, a light capture surface of a PEC cell as described herein is processed to be protected when submerged in a liquid electrolyte solution, and to improve light capture properties of the PEC cell. For example, a light capture surface of the photosensitive semiconductor material may be lightly doped in order to improve an ability to reflect charge carriers towards a buried junction of the PEC cell. As another example, the light capture surface of the semiconductor material is patterned to form a plurality of micropyramid structures to improve the light capture capability of PEC cell. As still another example, an insulator layer, such as silicon dioxide, is formed upon the light capture surface of the semiconductor layer to protect the photosensitive semiconductor from a solution when submerged. In still other examples, the insulator layer is also formed to include a plurality of micropyramid structures.

A PEC cell as described herein may provide significant benefits in comparison to other PEC cells. For example, the PEC cell described herein may exhibit superior light-harvesting capability over 95% in the wide range of solar spectrum from 300 to 1100 nm As another example, a single PEC cell as described herein may achieve a current density of 41.76 mA/cm2 for hydrogen evolution with an open-circuit potential of 0.62 V and a solar-to-hydrogen conversion efficiency (SHCE) of 11.44%. In some examples, a plurality of PEC cells may be coupled together to improve functionality. For example, three of the PEC cells described herein may be coupled in series and perform unassisted water splitting, with an SHCE of 15.62% with 240 μg.cm⁻²h⁻¹ of hydrogen. As another example, a PEC cell as described herein may provide for improved longevity when in operation submerged in an electrolyte solution such as liquid water, for example a PEC cell of this disclosure may operate for 40 hours or more.

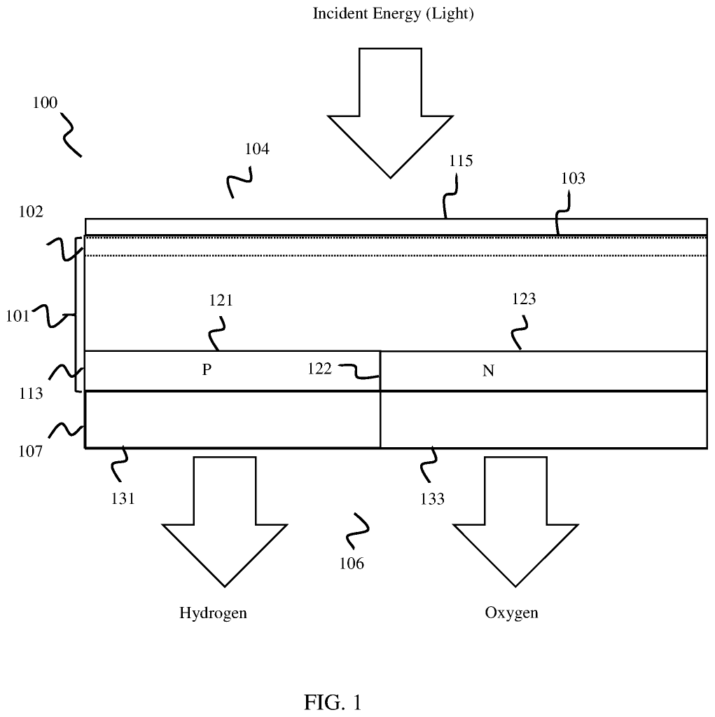

FIG. 1 is a conceptual diagram illustrating one example of a photoelectrochemical (PEC) cell 100 according to one or more aspects of this disclosure. PEC cell 100 is configured to use electromagnetic energy, such as sunlight, as an energy source to separate water molecules (H₂O) into hydrogen and oxygen atoms. Once split, the hydrogen atoms may be used as a fuel source, such as in a hydrogen fuel cell to power a home or automobile.

As shown in FIG. 1, PEC cell 100 includes a semiconductor layer 101, a first side 104, and a second side 106. First side 104 of PEC cell 100 includes a light capture surface 103, arranged to collect incident electromagnetic energy, such as sunlight. PEC cell 100 further includes a buried junction layer 113, and an electrode layer 107 at second side 106 proximal to the buried junction layer 113.

Semiconductor layer 101 is substantially formed of a semiconductor material, such as crystalline silicon. As depicted in FIG. 1, buried junction layer 113 includes a first portion 121 doped with a first doping type (e.g., P-type), and a second portion 123 doped with a second doping type different than the first doping type (e.g., N-type). An interface between first portion 121 and second portion 123 forms buried p-n junction 122.

First portion 121 is doped with material elements that cause first portion 121 to exhibit p-type semiconductor characteristics. For example, the first portion 121 may be doped with Boron (Br), or any other element that causes first portion 121 to exhibit P-type characteristics, such as Aluminum (Al) or Gallium (Ga). Second portion 123 is doped with material elements that cause the second portion to exhibit n-type semiconductor characteristics. For example, second portion 123 may be doped with Phosphorous (P), or any other element which causes second portion 109 to exhibit n-type characteristics, for example Antimony (Sb) or Arsenic (As).

As also shown in FIG. 1, buried junction 122 is arranged substantially perpendicular relative to light capture surface 103, referred to herein as a vertical junction. In contrast, a typical PEC cell includes a junction layer that is arranged in parallel to a light capture surface of the cell, referred to herein as a horizontal junction.

Electrode layer 107 includes electrodes 131, 133 each respectively in contact with first and second portions 121, 123 of semiconductor layer 101. In the example of FIG. 1, anode electrode 131 is electrically connected with first portion 121 of buried junction layer 113, while cathode electrode 133 is electrically connected with second portion 123 of buried junction layer 113.

At least a portion of electrodes 131, 133 respectively comprise materials and or coatings to facilitate the conversion of water atoms into hydrogen and oxygen atoms. For example, anode electrode 131 may be formed of or include one or more coatings that facilitate catalysis of oxygen atoms. As one particular example, at least a portion of electrode 131 includes Nickel (Ni) to facilitate catalysis of hydrogen atoms. At least a portion of cathode electrode 133 may be coated with or otherwise include additional materials that facilitate catalysis of oxygen atoms. As one particular example, electrode 133 may include or be coated with Platinum (Pt) to facilitate catalysis of oxygen atoms.

At least a portion of PEC cell 100 may be submerged in an electrolyte fluid, such as water (H₂O). When PEC cell 100 is submerged, and light capture surface 103 is exposed to light, electrical current may flow across buried junction 122, and thereby cause current to flow between anode electrode 131 and cathode electrode 133. When electrical current flows between them, electrodes 131 and 133 each respectively interact with the electrolyte fluid to catalyze hydrogen and oxygen atoms.

For example, sunlight incident on PEC cell 100 may excite free charge carriers (electrons and holes) at buried junction 122. Excited electrons may flow to cathode electrode 133, while exited holes may flow to anode electrode 131. At cathode 133, the four electrons react with four water molecules to form two molecules of hydrogen and four OH⁻ groups (4H₂O(1)+4e⁻2H₂(g)+4OH⁻(aq)). The OH⁻ groups flow through the liquid electrolyte to the surface of the anode electrode 131, wherein the four OH⁻ groups react with four holes, resulting in catalysis of two water molecules and an oxygen molecule (4OH⁻(aq)+4h⁺→O₂(g)+2H₂O(1)).

In this manner, PEC cell 100 functions to split water into hydrogen and oxygen, thereby converting received electromagnetic energy such as sunlight into a hydrogen “fuel.” Such a hydrogen fuel may then be used to power one or more hydrogen fuel cells, which advantageously supply easily transportable power with little or no polluting emissions.

As described above, a typical PEC cell includes an anode electrode at the light capture surface of the cell, and the cathode electrode is arranged elsewhere (e.g., an opposed surface of the cell). According to a such PEC cell, charge carriers travel between a wire connection between the anode electrode and the cathode electrode. In comparison, PEC cell 100 includes both anode and cathode electrodes at a same surface of the cell arranged proximally to buried junction layer 113, thereby enabling a shortened electrical connection between respective portions 121, 123 of buried junction layer 113 to the respective anode and cathode electrodes 131, 133.

As also shown in the example of FIG. 1, first side 104 of PEC cell 100 includes a passivation layer 115. In the example of FIG. 1, passivation layer 115 is formed upon light capture surface 103 to protect and/or improve light capture and other characteristics of semiconductor layer 101. Passivation layer 115 may comprise a layer of dielectric material, such as silicon dioxide, which protects semiconductor layer 101 from degredation and/or damage as a result of being submerged in an electrolyte fluid. In addition, passivation layer 115 may be patterned in order to improve light capture characteristics of semiconductor layer 101, for example to include a plurality of micropyramid structures which improve the ability of semiconductor layer 101 to capture and use light to generate electrical energy.

In some examples, a light capture surface 103 PEC cell 100 is processed to improve an ability of cell to generate electrical energy from received light. For example, light capture surface 103 may be lightly doped with a P-type semiconductor, such as Boron, which reduces recombination of electrical carriers (holes, electrons) at light capture surface 103. In additional examples, like passivation layer 115, light capture surface 103 is also patterned to include micropyramid structures that improve light capture characteristics of semiconductor layer 101.

PEC cell 100 shown in FIG. 1 does not include any metallization serving as an electrode at first side 104 that interfere with an ability of light capture surface 103 to capture light, as described with respect to typical PEC cells as discussed above. Instead, as shown in FIG. 1, both anode electrode 131 and cathode electrode 133 are arranged at second surface 106. In addition, PEC cell 100 shown in FIG. 1 includes at second side 106 a buried junction 122 arranged vertically (substantially perpendicular with respect to light capture surface 103), with anode electrode 131 and 133 in electrical contact with buried junction layer 122. In addition, as shown in FIG. 1, buried junction layer 113 is arranged proximate to both anode and cathode electrodes 131, 133 of electrode layer 107, thereby enabling a shortened electrical path in comparison with other PEC cells. The example PEC cell 100 depicted in FIG. 1 may exhibit significant advantages over other known PEC cells in terms of efficiency, performance, and device longevity.

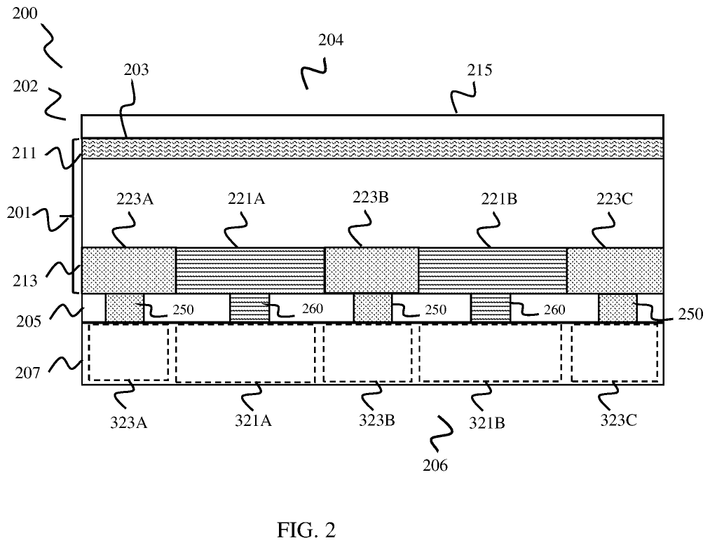

FIG. 2 is a conceptual diagram illustrating a side view of one example of a back buried junction PEC cell 200 according to one or more aspects of this disclosure. As shown in the example of FIG. 2, PEC cell 200 includes a semiconductor layer 201, which includes a light capture surface 203 arranged at a first side 204 of PEC cell 200, a buried junction layer 213, and an electrode layer 207 arranged at a second side 206 of PEC cell 200.

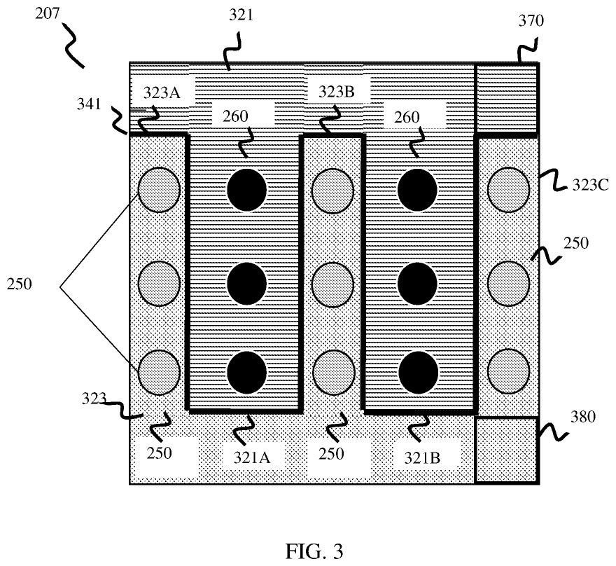

FIG. 3 is a conceptual diagram that illustrates one example of a top-down view of electrode layer 207, which includes an anode electrode 321 and a cathode electrode 323 separated by an insulator 341. As shown in the example of FIG. 3, anode electrode 321 includes a plurality of fingers 321A-321B, and cathode electrode 323 includes a plurality of fingers 323A-323C arranged in an alternating interdigitated pattern. In the example of FIG. 2, a relative location of each of fingers 321A-321B and 323A-323C depicted in FIG. 3 are shown by dashed boxes.

According to the example of FIGS. 2-3, buried junction layer 213 includes a plurality of first doped strips 221A-221B, and a plurality of second doped strips 223A-223C. Each of doped strips 221A-221C and 223A-223B extends backwards from the perspective of FIG. 2 into semiconductor layer 201. Doped first strips 221A-221B are arranged in an alternating pattern with doped second strips 223A-223C in junction layer 213, forming a plurality of vertical buried junctions in semiconductor layer 201.

Doped first strips 221A-221B are doped with a first doping type, for example p-doped (e.g., Boron doped). Doped second strips 223A-223C are doped with a second doping type different than the first doping type, for example n-doped (e.g., Phosphorous doped). In some examples, doped first strips 221A-221B may be wider than doped second strips 223A-223C, due to hole mobility of the p-doped first strips 221A-221B being less than electron mobility of the n-doped second strips 223A-223C. As a specific non-limiting example, doped first strips 221A-221B have a width of ˜400 μm, while doped second strips 223A-223C have a width of ˜250 μm.

In operation, when exposed to electromagnetic energy such as sunlight, the plurality of vertical buried junctions between first strips 221A-221B and second strips 223A-223C cause excitation of charge carriers (holes, electrons). Excited charge carriers may be transferred to anode electrode 321 and cathode electrode 323, which are configured to interact with an electrolyte solution PEC cell 200 is disposed in, to catalyze oxygen and hydrogen atoms, respectively.

As shown in the example of FIGS. 2-3, anode electrode 321 and cathode electrode 323 are formed to include electrode fingers 321A-321B and 323A-323C. As shown in the example of FIGS. 2-3, like first doped strips 221A-221B and second doped strips 223A-223C, the electrode fingers 321A-321B and 323A-323C are arranged in an alternating pattern . . . a first finger 321A of electrode 321 is arranged next to a first finger 323A of electrode 323, which is arranged next to a second finger 321B of electrode 321, which is arranged next to a second finger 323B of electrode 323, and so on.

As shown in the example of FIGS. 2-3, both doped strips 221A-221B, 223A-223C and electrode fingers 321A-321B and 323A-323C are arranged in an alternating pattern and proximal to one another, and are also arranged so that they generally align in a vertical dimension with one another so that a direct electrical connection can be formed between the respective strip and electrode finger. As an example, doped strip 221A is arranged vertically above and adjacent to electrode finger 321A, doped strip 232A is arranged vertically above and adjacent to electrode finger 323A, and so on. By arranging doped strips 221A-221B, 223A-223C in vertical alignment with electrode fingers 321A-321B and 323A-323C, a short electrical path is created between buried junction layer 213 and electrode layer 207, making for improved transfer of charge carriers (holes and electrons) from buried junction layer 213 to the respective anode 321 and cathode 323 electrodes in comparison to other PEC cells.

The example PEC cell 200 depicted in FIGS. 2 and 3 includes respective P and N portions of buried junction layer 213 arranged in alternating strips, and corresponding electrodes 321 and 323 include fingers arranged in an alternating interdigitated pattern that correspond vertically with and are proximal to the doped strips of buried junction layer. One of ordinary skill in the art will understand that both the P and N portions of buried junction layer 213 and corresponding electrodes 321, 323 depicted in FIGS. 2 and 3 may be arranged in different alternating patterns without departing from the scope of this disclosure. For example, although not depicted in FIGS. 2 and 3, the respective P and N portions of buried junction layer 213 may be arranged in any shape that alternates between respective P and N portions, for example concentric square shapes, concentric circle shapes, and the like. According to such examples, electrodes 321 and 323 may also be arranged in corresponding shapes alternating between the respective electrodes 321 and 323, vertically aligned with corresponding P and N portions of buried junction layer 213 to enable electrical connection between buried junction layer 213 and electrode layer 207.

In addition, the example of FIGS. 2 and 3 depicts one example where buried junction layer 113 includes two P-doped strips 221A and 221B, and three N-doped strips 223A-223B arranged in an alternating pattern, and two electrode fingers 321A, 321B corresponding to the P-doped strips 221A and 221B, and three electrode fingers 323A-323C corresponding to the N-doped strips 221A-221C. One of ordinary skill in the art will readily understand that a PEC cell consistent with this disclosure may include any number of alternating P and N-doped portions in buried junction layer 113, as well as any number of alternating electrode portions (fingers 321A-321B, 323A-323C) that correspond to the alternating P and N-doped portions.

In some examples, anode electrode 321 and cathode electrode 323 are formed of a conductive metal, such as aluminum. In some examples, at least a portion of exposed surfaces of anode electrode 321 and cathode electrode 323 may be coated with one or more materials to facilitate catalysis of hydrogen and oxygen atoms respectively. For example, an exposed surface of anode electrode 321, which is configured to catalyze oxygen, may be coated with or otherwise include Nickel (Ni) to facilitate generation and/or collection of oxygen atoms. As another example, an exposed surface of cathode electrode 323, which is configured to catalyze hydrogen, may be coated with or otherwise include Platinum (P1) to facilitate generate and/or collection of hydrogen atoms.

In the example of FIG. 3, each of anode electrode 321 and cathode electrode 323 include or are coupled to a respective contact portion 370, 380 configured to operate as a cocatalyst surface to catalyze oxygen or hydrogen, respectively. For example, as shown in FIG. 3, anode electrode 321 is coupled to a contact 370, which is coated with material(s) to facilitate catalysis of hydrogen, while cathode electrode 323 is coupled to contact 380 which is coated with material(s) to facilitate catalysis of hydrogen. According to these examples, the finger portions of each respective electrodes 321, 323 may not be in direct contact with an electrolyte solution, and may instead be covered with glass, epoxy, or another material to protect the electrode fingers from destruction or degradation when PEC cell 200 is submerged.

As also shown in FIG. 2, PEC cell includes an insulating interface layer 205. Insulating interface layer 205 provides electrical insulation between electrode layer 207 and buried junction layer 213, and allow electrical connections to be formed between electrode layer 207 and buried junction layer 213.

As also shown in FIGS. 2 and 3, each of anode electrode 321 and cathode electrode 323 are electrically coupled to respective doped first and second strips 221A-221B and 223A-223C through insulating interface layer 205. For this purpose, each of electrodes 321, 323 includes a respective plurality of vertical contacts 250, 260, that extend through insulating interface layer 205 to contact respective doped first and second strips 221A-221B and 223A-223C. According to the depicted example, fingers 321A-321B of anode 321 each include a plurality of vertical contacts 260 that extend through insulating interface layer 205 to contact doped first strips 221A-221B. Likewise, fingers 323A-323C of cathode 323 includes a plurality of vertical contacts 250 that extend through insulating interface layer 205 to contact doped first strips 223A-223C.

In some examples, insulating interface layer 205 is coated with an anti-reflective material, to reduce the reflection of light so that more light reaches buried junction layer 213 to be converted to electrical energy. For example, insulating interface layer 205 may be coated with an anti-reflection material such as SiNₓ, (e.g., silicon nitrate (SiN₂) or silicon nitride (SiN₃)). In some examples, a bottom surface of buried junction layer 113 may include a conductive material (not shown in FIG. 2) configured to be coupled to the respective vertical contacts 250, 260. For example, a bottom surface of buried junction layer 113 may include Tin (Sn) solder or another conductive material deposited beneath respective doped first and second strips 221A-221B and 223A-223C, for formation of an electrical connection with vertical contacts 250, 260.

As shown in the example of FIG. 1, first side 204 of PEC cell 200 includes a passivation layer 215. formed upon light capture surface 203 to protect and/or improve light capture and other characteristics of semiconductor layer 201. For example, passivation layer 215 may comprise a layer of dielectric material, such as silicon dioxide (SiO2), which protects semiconductor layer 201 from degredation and/or damage as a result of being submerged in an electrolyte fluid. In addition, passivation layer 215 may be patterned in order to improve light capture characteristics of semiconductor layer 201. For example, passivation layer 215 may be patterned to include a plurality of micropyramid structures which improve the capability of semiconductor layer 201 to capture and use light to generate electrical energy.

In some examples, light capture surface 203 that is treated to improve function of semiconductor layer 201 to generate electrical energy from received light. For example, light capture surface 203 may be lightly doped with a P-type semiconductor, such as Boron, which may reduce recombination of electrical carriers (holes, electrons) at light capture surface 203. In additional examples, like passivation layer 215, light capture surface 203 may also be patterned to include micropyramid structures that improve light capture characteristics of semiconductor layer 201.

Although not depicted in FIG. 2, in some examples, either or both of passivation layer 215 and/or light capture surface 203 may include an anti-reflective coating that improves light collection characteristics of PEC cell 200. For example, light capture surface 203 and/or passivation layer 215 may be coated with SiNx, which may reduce reflection and improve light capture characteristics of light capture surface 203. In still other examples, a bottom side 206 of PEC cell 200, including anode and cathode electrodes 321, 323, may also be coated with an anti-reflective material (e.g., SiNₓ) other than those portions configured to act as catalysts in contact with electrolyte fluid (e.g., contacts 370, 380).

Although the PEC cell 200 depicted in FIG. 2 includes both passivation layer 215 and a light capture surface 203 patterned to improve light capture and/or protection features of PEC cell 200. In other examples, a PEC cell consistent with this disclosure may include only a patterned light capture surface 203, or only passivation layer 215, without departing from the scope of this disclosure.

The exemplary PEC cell 200 depicted in FIGS. 2 and 3 may offer significant advantages in comparison to other PEC cells. For example, by arranging both of electrodes 321 and 323 on second side 206 of PEC cell 200 instead of at first side 204, catalytic electrodes do not interfere with the ability of semiconductor layer 201 to capture light, thereby increasing the efficiency of PEC cell 200. In addition, placing both anode and cathode electrodes 321 and 323 second side 206 corresponding to and proximal with buried junction layer 113 provides a short electrical path between buried junction layer 113 and electrode layer 207, thereby improving operating efficiency of PEC cell 200 to perform electrocatalysis. In addition, electrodes 321 and 323 in this arrangement serve as a bottom minor which causes reflection of photons not initially absorbed by junction layer 213 to be reflected back towards buried junction layer 213, thereby improving the efficiency of light capture for PEC cell 200.

PEC cell 200 depicted in FIGS. 2 and 3 may provide significant benefits in comparison to other PEC cells. For example, PEC cell 200 may exhibit superior light-harvesting capability over 95% in the wide range of solar spectrum from 300 to 1100 nm. As another example, a single PEC cell 200 may achieve a current density of 41.76 mA/cm2 for hydrogen evolution with an open-circuit potential of 0.62 V and a solar-to-hydrogen conversion efficiency (SHCE) of 11.44%. In some examples, a plurality of PEC cells 200 may be coupled together to provide even better performance For example, three of PEC cell 200 depicted in FIGS. 2 and 3 may be coupled in series and provide for an unassisted (without external electrical energy) SHCE of 15.62% with 240 μg.cm⁻²h⁻¹ of hydrogen.

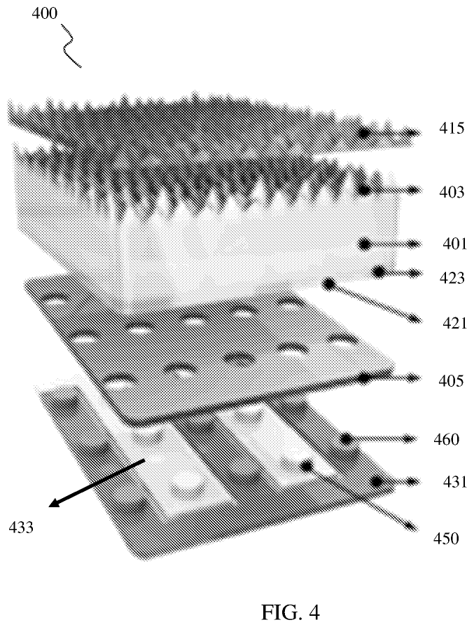

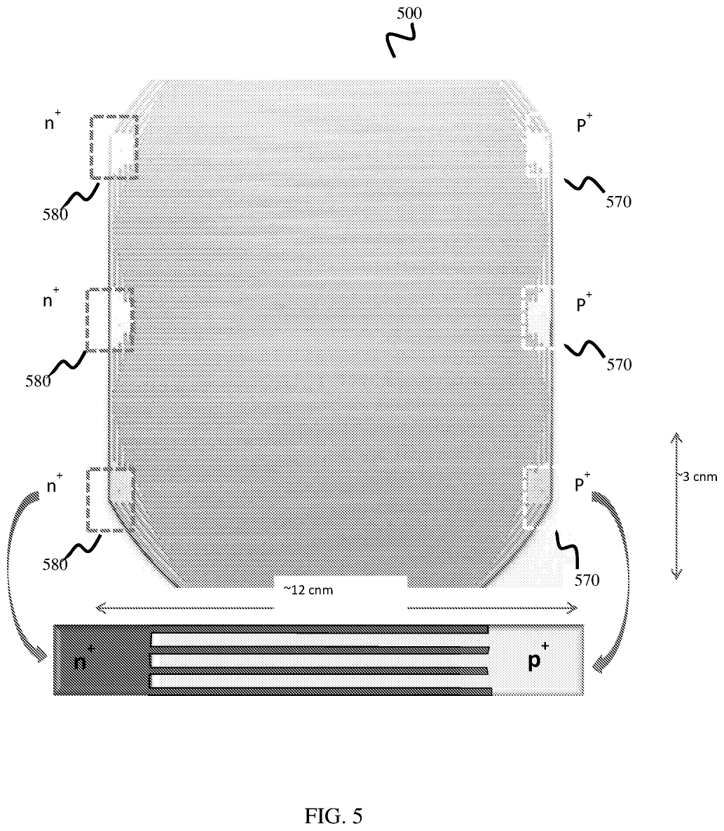

FIG. 4 is a conceptual diagram depicting one example of a PEC cell 400 consistent with this disclosure. As shown in FIG. 5, PEC cell 400 includes a semiconductor layer 401. Semiconductor layer 401 includes a buried junction layer, which includes a first plurality of first doped strips 421 alternately arranged with a plurality of second doped strips 423. PEC cell 400 further includes an electrode layer, which includes a first electrode 431 and a second electrode 433. As depicted, the first electrode 431 and second electrode 433 each include a plurality of fingers, which are arranged alternately interdigitated with one another. Furthermore, each finger of the respective electrodes includes a plurality of vertical contacts. For example, first electrode 431 includes vertical contacts 460, while second electrode 433 includes vertical contact 450.

As shown, PEC cell 400 further includes insulating interface layer 405. Insulating interface layer 405 is disposed between buried junction layer 413 and electrode layer 407. Insulating interface layer includes a plurality of apertures configured to receive vertical contacts 450, 460 of electrodes 431, 433 and couple them to doped strips 421, 423, respectively.

As also shown in the example of FIG. 4, a light capture surface 403 of semiconductor layer 401 is processed to improve performance of PEC cell 400 be doped (e.g., lightly p-doped) to reduce charge carrier recombination at the light capture surface. In addition, the light capture surface 403 may be patterned to improve light capture characteristics of PEC cell 400. As an example, as shown in FIG. 4, the light capture surface 403 is patterned to include micropyramids, which may improve the light collection efficiency of PEC cell 400.

As also shown in FIG. 4, PEC cell 400 includes passivation layer 415 formed on the light capture surface 403 of PEC cell 400. Passivation layer 415 includes an insulating layer formed upon semiconductor layer 401, for example a dielectric such as silicon dioxide. As also shown in FIG. 4, passivation layer 415 is patterned to include pyramid microstructures, which may improve light collection capability of PEC cell 400.

Although not depicted in FIG. 4, either, or both, light capture surface 403, passivation layer 415, and insulating interface layer 405 may be coated with an anti-reflective material (e.g., SiNₓ), that reduces an amount of light reflected from each respective surface. Such an anti-reflective coating may further improve the light capture capabilities of PEC cell 400.

FIG. 5 is a photographic image of one example of a PEC cell 500 according to one or more aspects of this disclosure. The example of FIG. 5 is a perspective view of a second side of PEC cell 500, showing a bottom surface of PEC cell (500) (opposite a light capture surface of PEC cell 500).

As shown in the example of FIG. 5, an anode electrode and a cathode electrode of PEC cell 500 each include a plurality of fingers arranged in an alternating, interdigitated pattern. As also shown in the example of FIG. 5, PEC cell 500 includes a plurality of P⁺ contacts 570, and a plurality of N⁺ contacts 580. P⁺ contacts 570 are coupled to the plurality of fingers of the anode electrode (which is coupled to the P⁺ strips of the PEC 500 buried junction layer not depicted in FIGS. 5), and N⁺ contacts are coupled to the plurality of fingers of the cathode electrode (which is coupled to the P⁺ strips of the PEC 500 buried junction layer not depicted in FIG. 5).

As described above with respect to FIGS. 2 and 3, an anode electrode of PEC cell 500 may include a material to facilitate catalysis of oxygen (Nickel), and a cathode electrode of PEC cell 500 may include a material to facilitate catalysis of hydrogen (e.g., Platinum). In some examples, an entire bottom surface of the respective electrodes may be coated with respective catalysis facilitating materials.

In still other examples, such as shown in FIG. 5, only contacts 570 and 580 themselves may be coated with catalysis facilitating materials, while a remainder of the respective electrodes (e.g., the fingers) are instead protected (e.g., via glass, epoxy) from exposure to electrolyte solution when submerged. For example, only P⁺ contacts 570 may be coated with a material to facilitate catalysis of oxygen (e.g., Nickel), and only N⁺ contacts 580 may be coated with a material to facilitate catalysis of hydrogen (e.g., Platinum).

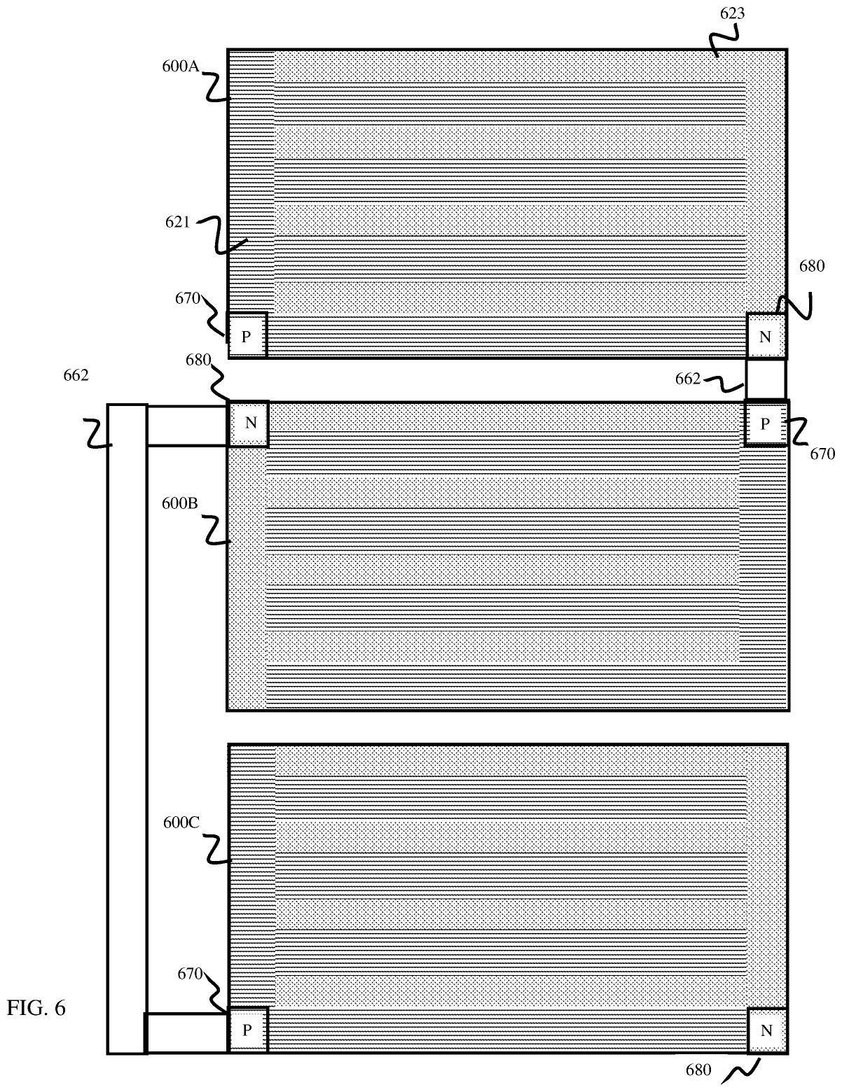

FIG. 6 is a conceptual diagram that depicts multiple PEC cells 600A-600C coupled together to form a PEC module 600 consistent with one or more aspects of this disclosure. As shown in FIG. 6, PEC module 600 includes three separate PEC cells 600A-600C, which each generally correspond to PEC cell 200 depicted and described with respect to FIGS. 2 and 3 above.

Each PEC cell 600A-600C includes an anode electrode 621 comprising a plurality of fingers, and a cathode electrode 623 comprising a plurality of fingers arranged in an interdigitated, alternating pattern with the plurality of fingers of the anode electrode 621, at least one P⁺ contact 670 coupled to the anode electrode 621, and at least one N⁺ contact 680 coupled to the cathode electrode 623. The P⁺ contacts 670 serve as a catalyst surface to facilitate catalysis of hydrogen , while the N⁺ contacts 680 serve as a catalyst surface to facilitate catalysis of oxygen.

In addition, the respective P⁺ and N⁺ contacts 670 may provide an electrical contact point, for coupling circuitry to perform measurements, or to electrically couple respective PEC cells 600A-600C to one another. For example, as shown in the FIG. 6 example, PEC cell 600A includes an N⁺ contact 680 coupled to a P⁺ contact 670 of PEC cell 600B via a conductor 662. As also shown in FIG. 6, PEC cell 600B includes an N⁺ contact 680 coupled to a P contact 670 of PEC cell 600C via conductor 662.

As shown in FIG. 6, a plurality of PEC cells 600A-600C may be coupled in series with one another (N⁺-contact to P⁺-Contact, N⁺-contact to P⁺-contact), in order for form a PEC module with advantageous operating characteristics. For example, a PEC module 600 comprising at least three PEC cells 600A-600C coupled together in series as shown in FIG. 6 may be capable of performing spontaneous (without electrical energy from an external source) of water into hydrogen and oxygen with a relatively high level of efficiency. As one specific example, PEC cells 600 as shown in FIG. 6 may provide for an unassisted SHCE of 15.62% with 240 μg·cm⁻²h⁻¹ of hydrogen.

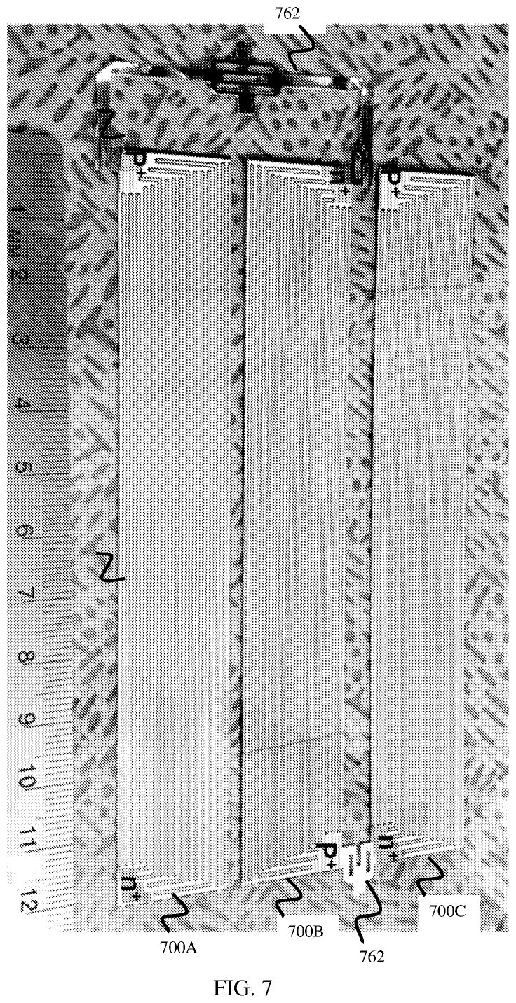

FIG. 7 is a photographic image depicting three PEC cells 700A-700C coupled to one another via conductors 762 in series. According to this example, a P⁺ contact of PEC cell 700C is coupled to an N⁺ contact of PEC cell 700B, while an N⁺ contact of PEC cell 700B is coupled to a P⁺ contact of PEC cell 700A.

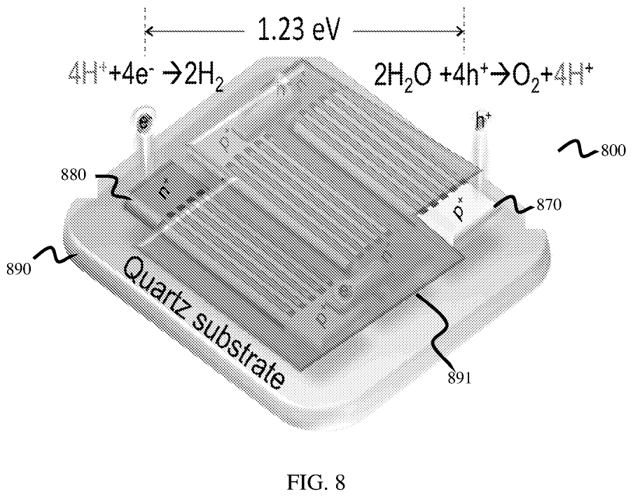

FIG. 8 is a conceptual diagram showing one example of a PEC module 800 according to one or more aspects of this disclosure. As shown in FIG. 8, PEC module 800 includes a plurality of PEC cells coupled to one another in series. Each PEC cell includes a P⁺ contact coupled to an anode electrode of the cell, and an N⁺ contact coupled to a cathode of the cell. As shown in FIG. 8, PEC module 800 includes a quartz or glass substrate 890 upon the individual PEC cells are placed and electrically coupled to one another. As further shown in FIG. 8, PEC module 800 includes a protective cover 891, which may comprise a material such as quartz or glass that covers a portion of the respective PEC cells other than an exposed N⁺ contact 880 and an exposed P⁺ contact 870. As shown in the example of FIG. 8, protective cover 891 is sized, shaped and arranged to cover a majority of the surface of the depicted PEC cells, while leaving the P⁺ and N⁺ contacts 870, 880 exposed.

Substrate 890 and Protective cover 891 may be formed of quartz or glass, or any other material that protects the respective PEC cells and components while allowing light to reach the light capture surfaces of the respective PEC cells of PEC module 800.

The respective exposed N⁺ contact 880 and exposed P⁺ contact 870 comprise the P⁺ (anode) and N⁺ cathode electrodes of the PEC module 800. Accordingly P⁺ contact 870 may be coated with a material to facilitate catalysis of oxygen, such as Nickel, while N⁺ contact 880 may be coated with a material to facilitate catalysis of hydrogen, such as Platinum.

PEC module 800 depicted in FIG. 8 is formed to maximize protection from an electrolyte solution in which PEC module 800 may be disposed. By sandwiching the depicted PEC cells between substrate 890 and protective cover 891, PEC module 800 may be resilient to the damaging effects an electrolyte solution can have on silicon and metals, and thereby extend a longevity of PEC cell 800. Although not depicted in FIG. 8, PEC module 800 may further include other materials or structures to improve resilience to an electrolyte environment, for example the components of PEC module may be sealed in an epoxy or other water resistant material.

As shown in FIG. 8, a PEC module 800 as described herein, which includes a plurality of PEC cells coupled in series, may overcome the voltage of (1.23 eV) required to perform unassisted (without external electrical stimulation) water splitting.

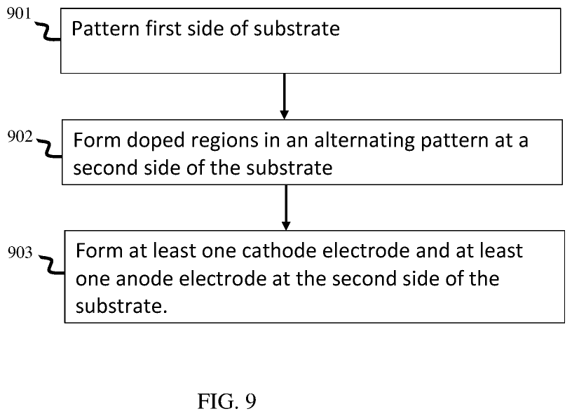

FIG. 9 is a flow diagram illustrating one example of a method of forming a photoelectrochemical (PEC) cell according to one or more aspects of this disclosure. As depicted in FIG. 9, at 901, a first side (204) of a semiconductor substrate (201) is patterned to improve light capture characteristics of the semiconductor substrate. For example, patterning the first side (204) may include texturing the first surface of the semiconductor substrate form micro pyramids. According some examples, patterning the first surface may comprise wet etching the first side (204) to form the micropyramids.

According to some examples not depicted in FIG. 9, the method further includes lightly P-doping the first side (204) to reduce charge carrier recombination at the first surface 203. For example, lightly P-doping may include implanting one or more ions including Boron, or any other element known to exhibit P-type characteristics when implanted in a semiconductor.

As also shown in FIG. 9, at 902, a plurality of doped regions are formed in an alternating pattern at a second surface (206) of the semiconductor substrate (201). For example, the plurality of doped regions may include one or more P⁺ regions and one or more N⁺ regions.

In some examples, the one or more P⁺ regions are a plurality of doped first strips (221A-221B), and the one or more N⁺ regions are a plurality of doped second strips (223A-223C) formed in an alternating pattern. In some examples, the one or more doped first strips (221A-221B) are wider than the one or more doped second strips (223A-223C). In some examples, the doped first strips (221A-221B) are P-doped strips formed by ion implantation of an element such as Boron (Br). As another example, the doped second strips (223A-223C) are n-doped strips formed by ion implantation with an element such as phosphorus (P).

In some examples, one or more of doped first strips 221A-221B and doped second strips 223A-223C may be additionally processed to form an electrical contact. For example, a Tin (Sn) foil may be soldered onto a bottom surface one or more of doped first and second strips (221A-221B and 223A-223C) to form electrical contacts. In still other examples, different metals may be used to form electrical contacts to doped first and second strips (221A-221B and 223A-223C). For example, Nickel may be formed on doped first strips (221A-221B) to form an electrical contact.

As also shown in FIG. 9, at 903, an anode electrode (323) and a cathode electrode (321) are formed at the second side (206) of the semiconductor substrate (201). For example, the anode electrode (321) and the cathode electrode (323) may be formed by depositing a conductive material such as aluminum on the second surface. Forming the anode and cathode electrodes on the second surface may include forming the anode and cathode to each include a plurality of fingers arranged in an alternating pattern. Forming the respective anode and cathode electrodes (321, 323) may further include forming an insulator between the anode electrode (321) and the cathode electrode (323) to electrically isolate them from one another. In some examples, forming the anode electrode (321) and the cathode electrode (323) includes creating a gap between the respective anode electrode (321) and cathode electrode (323) of ˜200 μm. In some examples, the fingers of the anode electrode have a width of ˜400 μm, and the fingers of the cathode electrode have a width of ˜250 μm.

Although not depicted in FIG. 9 at least a portion of the anode and at least a portion of the at least a portion of the cathode electrodes are coated with at least one cocatalyst material. For example, the anode electrode (321) may be coated with Nickel to facilitate catalysis of hydrogen atoms, and the cathode electrode (323) may be coated with Platinum to facilitate catalysis of oxygen atoms. In some examples, anode electrode 321 is coated by sputtering Nickel, and cathode electrode is formed by sputtering Platinum.

The PEC cell (200) may be heated to a temperature of ˜950 degrees C. to activate dopants at first side (204) and second side (206) of the PEC cell in a single step.

Although not depicted in FIG. 9, a passivation layer (215) may be formed at the first side (204). For example, an insulator material such as a dielectric material such as silicon dioxide (SiO₂) may be deposited upon light capture surface 203. In some examples, the deposited insulator material may have a depth of ˜40 nanometers. In some examples, the passivation layer (215) may be patterned to form micropyramid structures via wet etching.

Although not depicted in FIG. 9, in some examples, an anti-reflective coating is formed at one or more of the first and second sides (204, 206) of the PEC cell. For example, SiNₓ may be deposited on one or more of the first side (204) and the second side (206) by plasma enhanced chemical vapor deposition (PECVD).

In some examples, not shown in FIG. 9, once anode and cathode electrodes are formed and coated with the cocatalyst material, the PEC cell (200) may be substantially enclosed. For example, the PEC cell (200) may be sandwiched between glass or quartz sheets (990, 991) and sealed with a waterproof Epoxy (e.g., Hysol 11C), other than the surfaces (370, 380) of anode and cathode electrodes 321, 323 that may be exposed to an electrolyte solution when submerged so that they may function as hydrogen and oxygen cocatalyst electrodes, respectively.

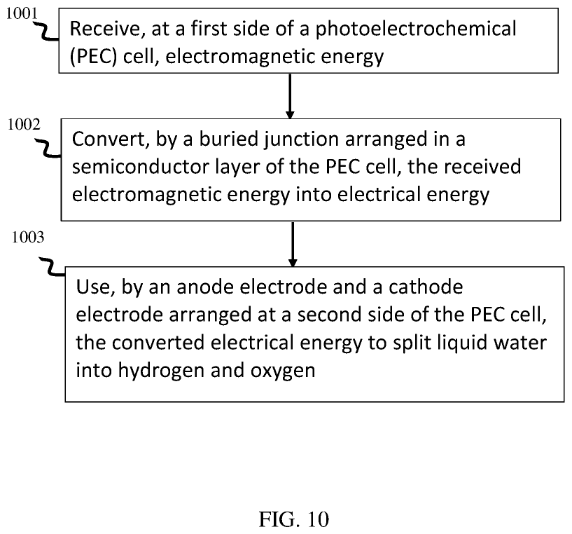

FIG. 10 is flow diagram depicted a method of operating a photoelectrochemical (PEC) cell (100, 200, 400, 500) according to one or more aspects of this disclosure. As shown in FIG. 10, at 1001, the method includes receiving, at a first side (204) of a PEC cell (200), electromagnetic energy (e.g., sunlight). The electromagnetic energy may be received at a light capture surface (203) of the PEC cell (200) that is patterned to improve light capture characteristics (e.g., patterned with micropyramids). In some examples, the first side (204) of the PEC cell (200) further includes an insulator layer (215) formed on the light capture surface (203), which may also be patterned to include micropyramid structures.

As shown in FIG. 10, at 1002, the method further includes converting, by a buried junction layer (213) arranged in the semiconductor layer (201) of the PEC cell (200), the received electrogagnetic energy into electrical energy. For example, when exited by sunlight, the buried junction layer (213) may excite charge carriers (holes, electrons), which may travel to the respective anode electrode (231) and cathode electrode (233), thereby causing an electrical current to flow. In some examples, the buried junction layer (213) includes a plurality of buried junctions arranged perpendicular to the first side (204) of the PEC cell (200).

As shown in FIG. 10, at 1003, the method further includes using, by an anode electrode 231 and a cathode electrode (233) arranged at a second side (206) of the PEC cell (200), the converted electrical energy to split liquid water into hydrogen and oxygen atoms. For example, the anode electrode (231) may include or be coupled to a P⁺ contact that includes one or more materials to facilitate catalysis of Oxygen, such as a Nickel coating, and the cathode electrode (233) may include or be coupled to an N⁺ contact that includes one or more materials to facilitate catalysis of Hydrogen, such as a Platinum coating. In some examples, the anode electrode (231) and the cathode electrode (233) each include a plurality of alternating interdigitated fingers sized, shaped and arranged to electrically connect to a plurality of alternating doped strips of the buried junction layer arranged proximal to the anode and cathode electrodes.

### Discussion of Possible Embodiments

The following are non-exclusive descriptions of possible embodiments of the present invention.

A photoelectrochemical (PEC) water splitting cell is comprised of a semiconductor layer and an electrode layer arranged at a second surface of the semiconductor layer. The semiconductor layer comprises a light capture surface arranged at a first side, wherein the semiconductor layer comprises a buried junction configured to convert incident electromagnetic energy into electrical energy. The electrode layer includes an anode electrode configured to catalyze hydrogen, and a cathode electrode configured to catalyze oxygen.

The PEC water splitting cell of the preceding paragraph can optionally include, additionally and/or alternatively any, one or more of the following features. configurations and/or additional components.

The PEC cell may further include wherein when the first and second electrode are in contact with an electrolyte solution comprising water and are supplied with electrical energy from the buried junction, the first and second electrodes catalyze water into hydrogen and oxygen.

The PEC cell may further include wherein the buried junction layer comprises a vertical buried junction layer.

The PEC cell may further include wherein the buried junction layer includes a first plurality of doped regions and a second plurality of doped regions arranged in an alternating pattern.

The PEC cell may further include wherein the buried junction layer includes the first plurality of doped regions comprising a plurality of N-type strips, and the second plurality of doped regions compring a plurality of P-type strips arranged in the alternating pattern.

The PEC cell may further include wherein the anode electrode comprises a first plurality of fingers and the cathode electrode comprises a second plurality of fingers arranged in an interleaved alternating pattern with the first plurality of fingers.

The PEC cell may further include wherein the first plurality of fingers of the anode electrode are sized, shaped, and arranged to align with and electrically connect to a plurality of n-doped strips of the buried junction layer, and the second plurality of fingers of the cathode electrode are sized, shaped, and arranged to align with and electrically connect to a plurality of p-doped strips of the buried junction layer.

The PEC cell may further comprise an insulator layer arranged between the electrode layer and the buried junction layer, wherein the first electrode is electrically connected to the plurality of n-doped strips and the second electrode is electrically connected to the plurality of p-doped strips through the insulator layer.

The PEC cell may further include wherein the buried junction is arranged proximal to and electrically coupled with the electrode layer.

In another embodiment, a method of forming a photoelectrochemical cell. The method includes patterning a first side of a semiconductor substrate. The method further includes doping a second side of the semiconductor substrate to form a buried junction layer, wherein the buried junction layer comprises a first plurality of doped regions and a second plurality of doped regions arranged in an alternating pattern, and forming an electrode layer at the second side of the semiconductor substrate, wherein the electrode layer includes an anode electrode comprising a first plurality of fingers arranged in an interdigitated alternating pattern with a cathode electrode comprising a second plurality of fingers.

The method of the preceding paragraph can optionally include, additionally and/or alternatively any, one or more of the following features, configurations and/or additional components.

The method may further include electrically coupling the first plurality of doped regions to anode electrode and the second plurality of doped regions to the cathode electrode.

The method may further include depositing a passivation layer on the first side of the semiconductor substrate.

In another embodiment, a method includes receiving, at a first side of a photoelectrochemical (PEC) cell, electromagnetic energy. The method further includes converting, via a buried junction of the PEC cell, the received electromagnetic energy into electrical energy and using, at an anode electrode and a cathode electrode arranged at a second side of the PEC cell, the converted electrical energy to catalyze water into hydrogen and oxygen.

The method of the preceding paragraph can optionally include, additionally and/or alternatively any, one or more of the following features, configurations and/or additional components.

The method may further include electrically coupling the first plurality of doped regions to the anode electrode and the second plurality of doped regions to the cathode electrode.

The method may further include depositing a passivation layer on the first side of the semiconductor substrate.

The method may further include receiving, at a first side of a photoelectrochemical (PEC) cell, electromagnetic energy. The method may further include converting, via a buried junction of the PEC cell, the received electromagnetic energy into electrical energy and using, at an anode electrode and a cathode electrode arranged at a second side of the PEC cell, the converted electrical energy to catalyze water into hydrogen and oxygen.

The method may further include submerging at least a portion of the PEC cell in an electrolyte solution, wherein the anode electrode and the cathode electrode interact with the electrolyte solution to catalyze hydrogen and oxygen.

The method may further include wherein the buried junction comprises a vertical buried junction.

The method may further include wherein the buried junction comprises a first plurality of doped regions and a second plurality of doped regions arranged in an alternating pattern.

The method may further include wherein the buried junction layer includes the first plurality of doped regions comprising a plurality of N-type strips, and the second plurality of doped regions comprising a plurality of P-type strips arranged in the alternating pattern.

The method may further include wherein the anode electrode comprises a first plurality of fingers and the cathode electrode comprises a second plurality of fingers arranged in an interleaved alternating pattern with the first plurality of fingers.

The method may further include wherein the first plurality of fingers of the anode electrode are sized, shaped, and arranged to align with and electrically connect to a plurality of n-doped strips of the buried junction layer, and the second plurality of fingers of the cathode electrode are sized, shaped, and arranged to align with and electrically connect to a plurality of p-doped strips of the buried junction layer.

The method may further include wherein the buried junction is arranged proximal o and electrically coupled with the electrode layer.

1. A photoelectrochemical (PEC) water splitting cell, comprising:
a semiconductor layer comprising a light capture surface arranged at a first side, wherein the semiconductor layer comprises a buried junction configured to convert incident electromagnetic energy into electrical energy; and
an electrode layer arranged at a second surface of the semiconductor layer that includes an anode electrode configured to catalyze hydrogen, and a cathode electrode configured to catalyze oxygen.

2. The PEC cell of claim 1, wherein, when the first and second electrode are in contact with an electrolyte solution comprising water and are supplied with electrical energy from the buried junction, the first and second electrodes catalyze water into hydrogen and oxygen.

3. The PEC cell of claim 1, wherein the buried junction layer comprises a vertical buried junction layer.

4. The PEC cell of claim 1, wherein the buried junction layer includes a first plurality of doped regions and a second plurality of doped regions arranged in an alternating pattern.

5. The PEC cell of claim 4, wherein the buried junction layer includes the first plurality of doped regions comprising a plurality of N-type strips, and the second plurality of doped regions comprising a plurality of P-type strips arranged in the alternating pattern.

6. The PEC cell of claim 1, wherein the anode electrode comprises a first plurality of fingers and the cathode electrode comprises a second plurality of fingers arranged in an interleaved alternating pattern with the first plurality of fingers.

7. The PEC cell of claim 4, wherein the first plurality of fingers of the anode electrode are sized, shaped, and arranged to align with and electrically connect to a plurality of n-doped strips of the buried junction layer, and the second plurality of fingers of the cathode electrode are sized, shaped, and arranged to align with and electrically connect to a plurality of p-doped strips of the buried junction layer.

8. The PEC cell of claim 7, further comprising:
an insulator layer arranged between the electrode layer and the buried junction layer, wherein the first electrode is electrically connected to the plurality of n-doped strips and the second electrode is electrically connected to the plurality of p-doped strips through the insulator layer.

9. The PEC cell of claim 1, wherein the buried junction is arranged proximal to and electrically coupled with the electrode layer,

10. A method of forming a photoelectrochemical cell, comprising:
patterning a first side of a semiconductor substrate;
doping a second side of the semiconductor substrate to form a buried junction layer, wherein the buried junction layer comprises a first plurality of doped regions and a second plurality of doped regions arranged in an alternating pattern; and
forming an electrode layer at the second side of the semiconductor substrate, wherein the electrode layer includes an anode electrode comprising a first plurality of fingers arranged in an interdigitated alternating pattern with a cathode electrode comprising a second plurality of fingers.

11. The method of claim 10, further comprising:
electrically coupling the first plurality of doped regions to anode electrode and the second plurality of doped regions to the cathode electrode.

12. The method of claim 10, further comprising:
depositing a passivation layer on the first side of the semiconductor substrate.

13. A method, comprising:
receiving, at a first side of a photoelectrochemical (PEC) cell, electromagnetic energy;
converting, via a buried junction of the PEC cell, the received electromagnetic energy into electrical energy; and
using, at an anode electrode and a cathode electrode arranged at a second side of the PEC cell, the converted electrical energy to catalyze water into hydrogen and oxygen.

14. The method of claim 13, further comprising:
submerging at least a portion of the PEC cell in an electrolyte solution, wherein the anode electrode and the cathode electrode interact with the electrolyte solution to catalyze hydrogen and oxygen.

15. The method of claim 13, wherein the buried junction comprises a vertical buried junction.

16. The method of claim 13, wherein the buried junction comprises a first plurality of doped regions and a second plurality of doped regions arranged in an alternating pattern.

17. The method of claim 16, wherein the buried junction layer includes the first plurality of doped regions comprising a plurality of N-type strips, and the second plurality of doped regions comprising a plurality of P-type strips arranged in the alternating pattern.

18. The method of claim 13, wherein the anode electrode comprises a first plurality of fingers and the cathode electrode comprises a second plurality of fingers arranged in an interleaved alternating pattern with the first plurality of fingers.

19. The method of claim 18, wherein the first plurality of fingers of the anode electrode are sized, shaped, and arranged to align with and electrically connect to a plurality of n-doped strips of the buried junction layer, and the second plurality of fingers of the cathode electrode are sized, shaped, and arranged to align with and electrically connect to a plurality of p-doped strips of the buried junction layer.

20. The method of claim 13, wherein the buried junction is arranged proximal to and electrically coupled with the electrode layer.
